(19) United States
(12) Patent Application Publication
(10) Pub. No.: US 2006/0131657 A1
(43) Pub. Date: Jun. 22, 2006

(54) Semiconductor integrated circuit device and method for the same

(75) Inventor: Masafumi Hamaguchi, Kawasaki-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/296,705

(22) Filed: Dec. 8, 2005

(30) Foreign Application Priority Data
Dec. 10, 2004 (JP) 2004-358831

(51) Int. Cl. H01L 29/94; H01L 31/062

(52) U.S. Cl. 257/369; 257/296; 257/368

(57) ABSTRACT

In a surface region of a semiconductor substrate, an element isolation region for isolating the substrate into a plurality of element regions is formed. In each of the plurality of element regions, a pair of trenches, which are formed apart from each other and each have a bottom surface and side surfaces, are formed. Further, an insulation film is formed on each of the bottom surfaces in the pair of trenches, and on the insulation film, a source region and a drain region are formed so as to embed the inside of the pair of trenches. In addition, a channel region which is interconnected to the semiconductor substrate is formed between the source region and a drain region, and a gate electrode is formed on each channel region.

### CROSS-REFERENCE TO RELATED APPLICATIONS

This application is based upon and claims the benefit of priority from prior Japanese Patent Application No. 2004-358831, filed Dec. 10, 2004, the entire contents of which are incorporated herein by reference.

### BACKGROUND OF THE INVENTION

1. Field of the Invention

The present invention relates to a semiconductor integrated circuit device where MOSFETs are integrated, and particularly to a semiconductor integrated circuit device to which a low power consumption and a high performance are required.

2. Description of the Related Art

In the use of a silicon-based semiconductor device in fields where a low power consumption and a high performance are required, a silicon on insulator (SOI) structure is employed. As an example of an insulation gate type field-effect transistor (hereinafter referred to as MOSFET) using the SOI structure, there is one that is formed on a Si layer on an oxide film embedded in a Si substrate. Such a MOSFET of the SOI structure realizes a reduction in the junction capacitance between a source region or a drain region and a substrate, and a reduction in the leak current flowing from the source region and the drain region to the substrate.

However, problems with the MOSFET having the SOI structure includes its self heating effect owing to the low heat transmission rate of the embedded oxide film, and its substrate floating effect owing to the insulation of the Si substrate due to the presence of the embedded oxide film. On the other hand, in recent years, it has been necessary to improve the carrier mobility of the MOSFET in order to realize a high driving capacity.

U.S. Pat. No. 5,747,847 discloses a semiconductor integrated circuit device where an embedded oxide film is not formed over the whole face of a P-type silicon layer but has an opening in a region which is placed below a gate electrode, the opening is filled in to form a penetration P layer, accordingly, a SOI layer is electrically connected to the P type silicon layer through the penetration P layer.

### BRIEF SUMMARY OF THE INVENTION

According to a first aspect of the present invention, there is provided a MOS type semiconductor integrated circuit device comprising: an element isolation region which is formed in the surface region of a semiconductor substrate, and isolates the substrate into a plurality of element regions; a pair of trenches which is formed apart in each of the plurality of element regions, and each has a bottom surface and side surfaces; an insulation film having at least a first portion positioned on each bottom surface in the pair of trenches; a source region and a drain region formed on the insulation film, and formed on the inside of the pair of trenches; a channel region which is formed between the source region and the drain region, and is interconnected to the semiconductor substrate; and a gate electrode formed on each channel region.

According to a second aspect of the present invention, there is provided a method of manufacturing a MOS type semiconductor integrated circuit device, comprising: forming an element isolation region in a surface region of a silicon semiconductor substrate, and isolating the substrate into a plurality of element regions; forming a gate electrode on each of the plurality of element regions; etching and removing the substrate by using each gate electrode as a mask, and forming a pair of trenches in the substrate of the plurality of element regions; forming a silicon nitride film composed of a first portion which is positioned on the bottom surface of each of the pair of trenches, and a second portion which is positioned on the side surfaces of the trench and whose upper surface is lower than the upper surface of the substrate before etching for each trench; performing an epitaxial growth of silicon with the silicon substrate under the gate electrode as a seed, and forming a single crystal silicon layer on the silicon nitride film; flattening the upper surface of each single crystal silicon layer; and introducing impurities into each single crystal silicon layer and forming a source region and a drain region.

### BRIEF DESCRIPTION OF THE SEVERAL VIEWS OF THE DRAWING

FIG. 1 is a cross sectional view showing an element structure of a CMOS type semiconductor integrated circuit device according to a first embodiment of the present invention;

FIG. 2A is a cross sectional view showing a step of a part of a first method of manufacturing the semiconductor integrated circuit device of FIG. 1;

FIG. 2B is a cross sectional view showing the next step of FIG. 2A;

FIG. 2C is a cross sectional view showing the next step of FIG. 2B;

FIG. 2D is a cross sectional view showing the next step of FIG. 2C;

FIG. 2E is a cross sectional view showing the next step of FIG. 2D;

FIG. 2F is a cross sectional view showing the next step of FIG. 2E;

FIG. 2G is a cross sectional view showing the next step of FIG. 2F;

FIG. 2H is a cross sectional view showing the next step of FIG. 2G;

FIG. 2I is a cross sectional view showing the next step of FIG. 2H;

FIG. 3A is a cross sectional view showing a step of a part of a second method of manufacturing the semiconductor integrated circuit device of FIG. 1;

FIG. 3B is a cross sectional view showing the next step of FIG. 3A;

FIG. 3C is a cross sectional view showing the next step of FIG. 3B;

FIG. 3D is a cross sectional view showing the next step of FIG. 3C;

FIG. 3E is a cross sectional view showing the next step of FIG. 3D;

FIG. 3F is a cross sectional view showing the next step of FIG. 3E;

FIG. 3G is a cross sectional view showing the next step of FIG. 3F; and

FIG. 4 is a cross sectional view showing an element structure of a CMOS type semiconductor integrated circuit device according to a second embodiment of the present invention.

### DETAILED DESCRIPTION OF THE INVENTION

Embodiments of the present invention will be illustrated in more details with reference to the accompanying drawings hereinafter. Meanwhile, in all the drawings for explaining the embodiments, the same functional components are denoted by the same reference numerals.

### FIRST EMBODIMENT

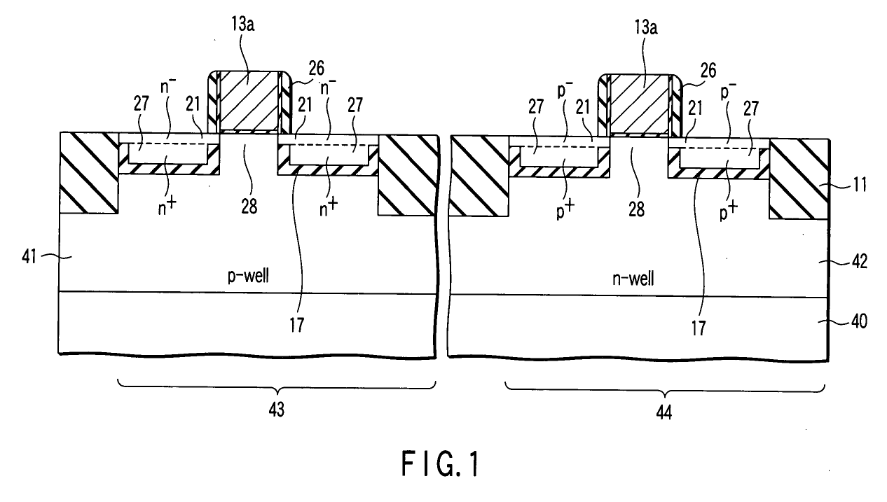

FIG. 1 is a cross sectional view showing an element structure of a CMOS type semiconductor integrated circuit device. A p-well 41 and an n-well 42 are formed in the upper surface region of a p-type or n-type Si semiconductor substrate 40. The p-well 41 and the n-well 42 are respectively isolated into a plurality of element regions by an STI 11 of a shallow trench structure. The plurality of element regions each include an nMOS element region 43 on which an nMOSFET is formed, and a pMOS element region 44 on which a pMOSFET is formed. In FIG. 1, one nMOS element region 43 and one pMOS element region 44 are shown. In an actual integrated circuit device, however, a plurality of the nMOS element regions 43 and pMOS element regions 44 are formed respectively.

In the nMOS element region 43 and pMOS element region 44, a pair of trenches, which are apart from each other and each have a bottom surface and side surfaces, are formed in the p-well 41 and the n-well 42. Further, an insulation film (embedded insulation film) 17 is formed in the pair of trenches. The insulation film (embedded insulation film) 17 is composed of a first portion positioned on the bottom surface of each trench, and a second portion positioned at the side surfaces of each trench and integrated with the first portion. In each pair of trenches, a source/drain region 27 is formed so as to embed the inside of each trench. A channel region 28 between the source/drain regions 27 is interconnected to the p-well 41 or the n-well 42. Namely, the channel region 28 is not insulated from the p-well 41 or n-well 42 and the substrate 40.

In FIG. 1, reference numeral 13a is a gate electrode of MOSFET made of, for example, polysilicon, 21 is an n-type or p-type extension region configuring a part of the source/drain region 27, and 26 is a side wall insulation film arranged at each side wall of the gate electrode 13a.

In the CMOS type semiconductor integrated circuit device having the structure as shown in FIG. 1, the embedded insulation film 17 is formed at the bottom surface of the source/drain region 27 of each MOSFET formed on the Si semiconductor substrate 40 and the side surfaces of the source/drain region 27 and under the extension region 21. The upper surface of the second portion of the embedded insulation film 17 arranged at the side surfaces of the source/drain region 27 is at a position lower than the bottom surface of the extension region 21. Further, the channel region 28 of each MOSFET is interconnected to the p-well 41 or the n-well 42.

As described above, since each channel region 28 is not insulated from the Si semiconductor substrate 40, it is possible to avoid the self heating effect and the substrate floating effect. The bottom surface of the source/drain region 27 contacts the embedded insulation film 17. For this reason, it is possible to reduce the junction capacitance and the leak current of the source/drain region 27. Furthermore, since the low cost Si semiconductor substrate 40 is used as a bulk substrate, it is possible to manufacture the integrated circuit device at low costs.

Moreover, the embedded insulation film 17 is formed, and therefore, it is possible to cause stress to work onto the channel region 28 of each MOSFET, and to control the carrier mobility in the channel region 28. In the case where the semiconductor substrate 40 is a Si semiconductor substrate, a silicon nitride film (Si₃N₄ film) formed by, for example, a thermal CVD (Chemical Vapor Deposition) method is used as the embedded insulation film 17 of the nMOS element region 43, thereby making it possible to cause tensile stress to work onto the channel region of the nMOSFET. Meanwhile, it is desirable that the embedded insulation film 17 of the PMOS element region 44 is one that is processed so as to weaken the tensile stress to the channel region of the pMOSFET, or one that has a film quality for causing compression stress to work onto the channel region of the pMOSFET. In order to make the compression stress work onto the channel region of the pMOSFET, a silicon nitride film (Si₃N₄ film) formed by, for example, a plasma CVD method may be used as the embedded insulation film 17 of the pMOS element region 44.

(First Manufacturing Method)

Next, an example of a method of manufacturing the CMOS type semiconductor integrated circuit device in FIG. 1 will be explained. Meanwhile, the manufacturing method is not limited to the method explained hereinafter, and, either a gate pre-creation process where the gate electrode is formed in prior to the embedded insulation film, or a gate post-creation method where the gate electrode is formed after the embedded insulation film may be employed.

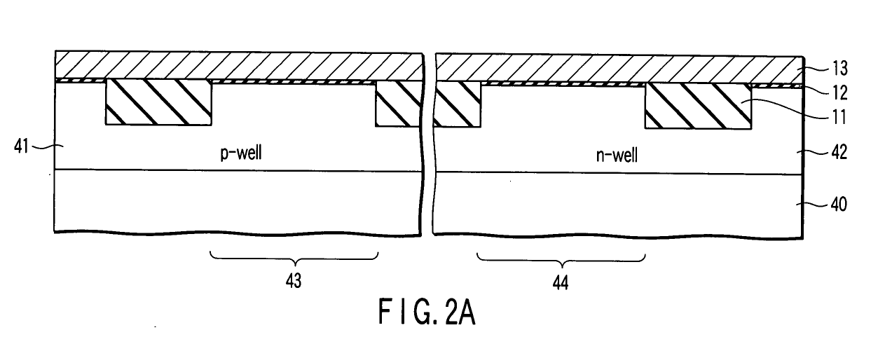

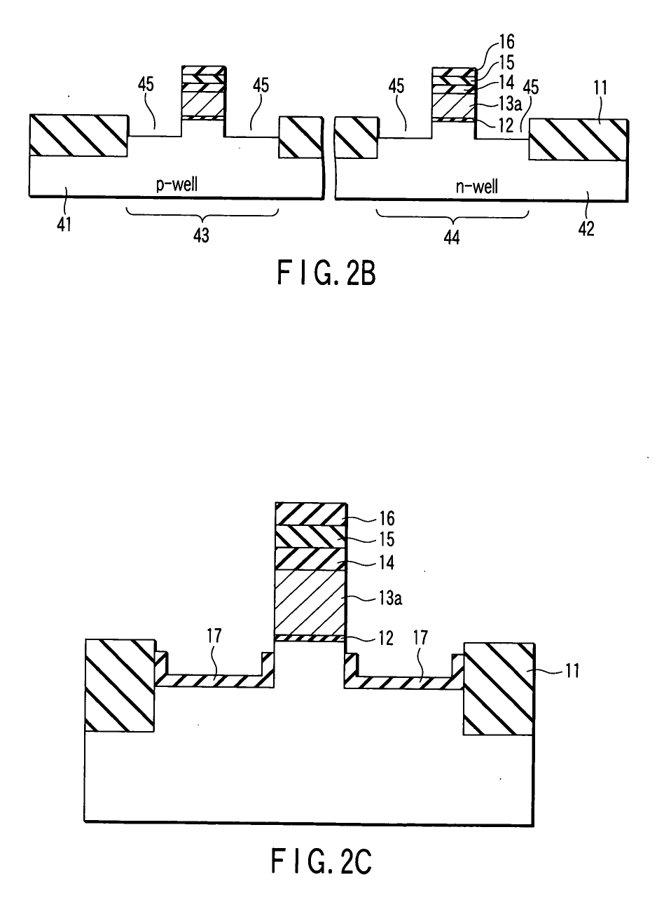

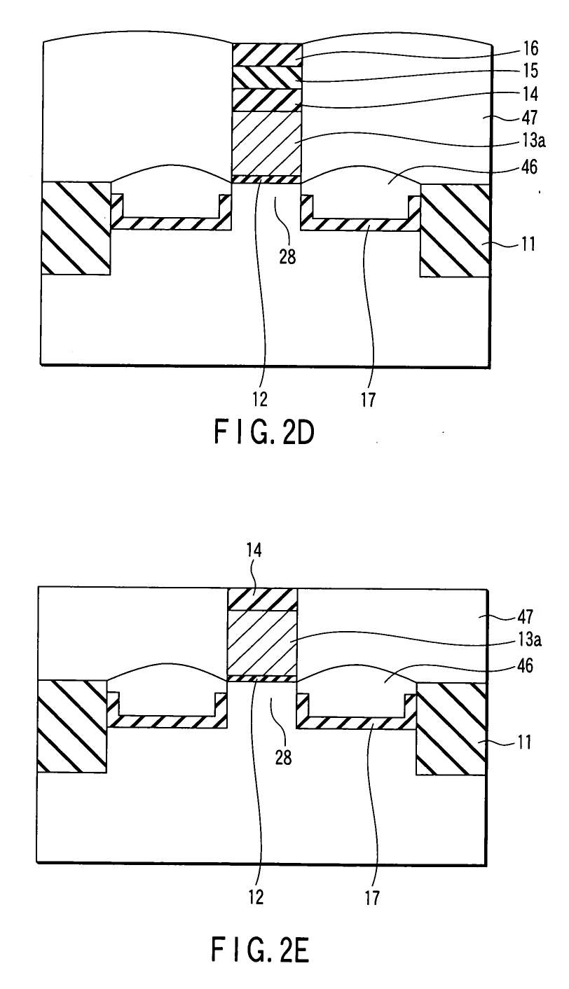

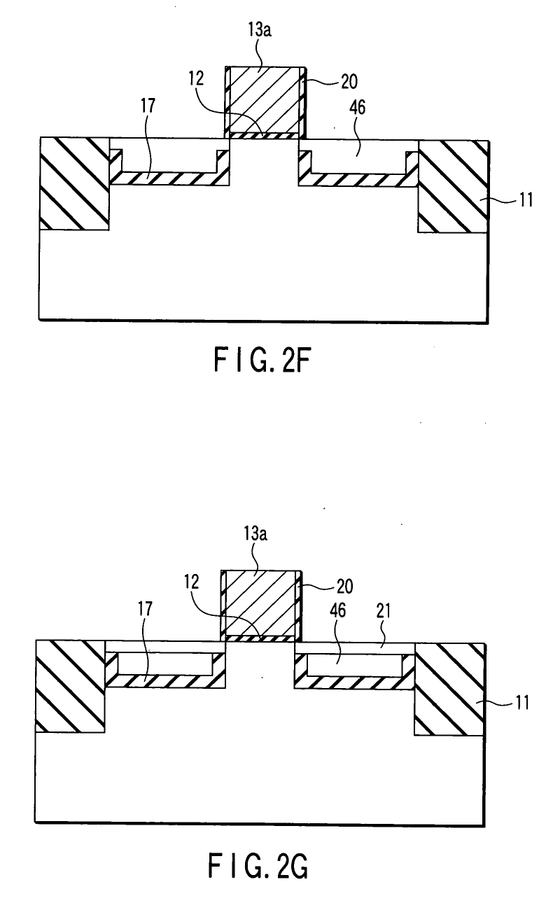

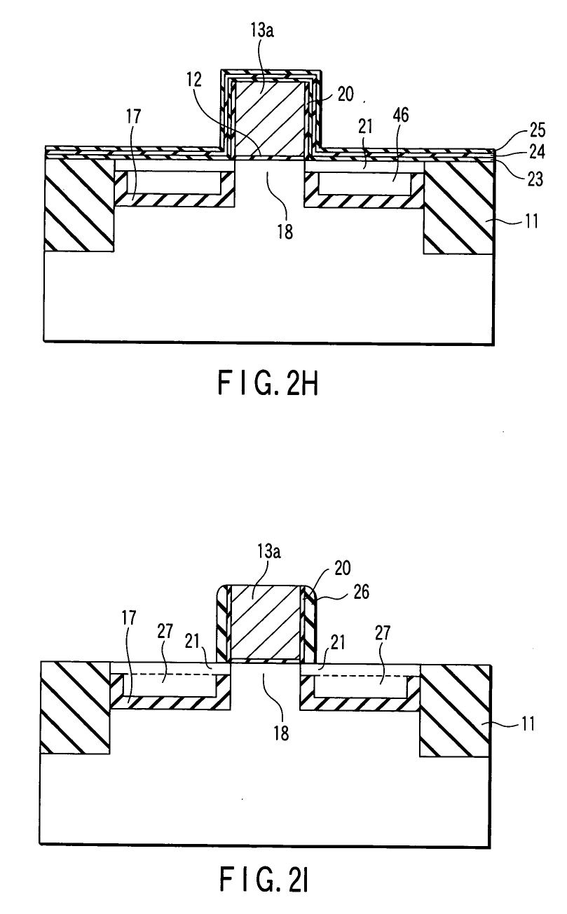

FIGS. 2A to 2I show cross sectional structures in manufacturing the CMOS type semiconductor integrated circuit device in FIG. 1 in accordance with the flow of the gate pre-creation process. FIGS. 2A and 2B show the cross sections of the nMOS element region 43 and the pMOS element region 44, and FIGS. 2C to 2I each show an enlarged view of one of the nMOS element region and the pMOS element region, for simplified illustration.

First, as shown in FIG. 2A, a shallow trench is formed in the surface region of the p-type or n-type Si semiconductor substrate 40, and an insulation film, for example, a silicon oxide is filled in the inside thereof, and thereby the STI 11 is formed. Subsequently, the p-well 41 and the n-well 42 are formed in the surface region of the Si semiconductor substrate 40. Next, an oxide film is grown, for example, 1 nm on the Si semiconductor substrate 40, and plasma nitriding is performed, thereby an oxide film 12 whose effective oxide thickness is, for example, 1.3 nm, is formed. Further, a polysilicon film 13 for forming a gate electrode is deposited on the oxide film 12. The film thickness of the polysilicon film 13 is, for example, around 150 nm, though it depends upon generations of circuit line width of manufacturing technologies. Meanwhile, in a state before gate processing as mentioned above, pre-doping of phosphor (P) ion is performed to the polysilicon film 13 of the nMOS element region with an acceleration voltage 5 keV, and a dose amount 5e15. Pre-doping may not be performed to the polysilicon film 13 of the pMOS element region.

Next, as shown in FIG. 2B, a Si₃N₄ film 14, an amorphous silicon film 15, and an anti reflective coating (ARC) film 16 are deposited sequentially, and the three-layer film is patterned to thereby form a mask for gate processing. Subsequently, by use of the mask, the polysilicon film 13 is processed by a reactive ion etching (RIE) method, and thereby the gate electrode 13a is formed. At this moment, the Si₃N₄ film 14 is first deposited on the polysilicon film 13 as a hard mask. Next, a COM process using hydro chloric acid-ozone-mixture is performed as a preprocessing, and then, a rapid thermal oxidation (RTO) process is performed. Thereafter, the amorphous silicon film 15 is deposited, and the ARC film 16 is deposited thereon. The ARC film 16, and the amorphous silicon film 15 are selectively etched by the RIE method. Thereafter, the amorphous silicon film 15 is slimed by isogonic etching. The gate length of the MOSFET manufactured by the present method is, for example, 40 nm, and the dimension 0.11 μm on the mask is shrunk into around 40 nm by the above slimming. Thereafter, the Si₃N₄ film 14 is etched by the RIE method, and further the polysilicon film 13 is etched by the RIE method to form the gate electrode 13a. Then, other regions than the active region of the MOSFET are covered with the resist pattern, and the oxide film 12 and the portions corresponding to the source/drain region of the Si semiconductor substrate 40 thereunder are etched by the RIE method, so that a pair of trenches 45 are formed in each element region. At this moment, the etching amount of the Si semiconductor substrate 40, i.e., the depth of the pair of trenches 45 is determined according to the junction depth of the source/drain region of the MOSFET, and the film thickness of an embedded insulation film 17 to be formed later, and is, for example, around 150 nm.

Next, as shown in FIG. 2C, the Si₃N₄ film 14 is deposited around 50 nm and thereby the embedded insulation film 17 is formed. The embedded insulation film 17 attaches onto not only the bottom surface of the trench 45 where the Si semiconductor substrate 40 is etched, but also the side surfaces of the STI 11. Namely, the embedded insulation film 17 is composed of a first portion positioned on the bottom surface of each trench 45, and a second portion positioned at the side surfaces of each trench 45, and integrated with the first portion. The upper surface of the second portion is lower than the upper surface of the original substrate 40. The embedded insulation film 17 is formed by depositing a silicon nitride film (Si₃N₄ film) by the thermal CVD method.

Next, epitaxial growth of Si is performed as shown in FIG. 2D. At this moment, the plain orientation of a single crystal Si layer 46 that grows with the single crystal Si of the channel region 28 under the gate electrode 13a as its seed differs from that of a polycrystal Si layer 47 that grows with the polysilicon of the gate electrode 13a as its seed, and the inside of the trench 45 is embedded with the single crystal Si layer 46 that grows from the channel region 28.

Thereafter, as shown in FIG. 2E, the ARC film 16 and the amorphous silicon film 15 on the gate electrode 13a are etched and removed, and the Si₃N₄ film 14 is left. Subsequently, the polycrystal Si layer 47 is scraped to the height of the Si₃N₄ film 14 by chemical mechanical polishing (CMP). Then, by the RIE method with the Si₃N₄ film 14 as a mask, the polycrystal Si layer 47 is removed, and the single crystal Si layer 46 is removed until it gets at the height of the original Si semiconductor substrate 40, as shown in FIG. 2F. Next, the Si₃N₄ film 14 is removed with hot phosphoric acid. Then, as a post oxide process of the surface of the gate electrode 13a, an oxide film of 2 nm is formed by the RTO.

Thereafter, a MOSFET having, for example, a lightly doped drain (LDD) structure is completed by a process similar to the conventional process. First, as shown in FIG. 2F, a TEOS film is deposited, for example, around 9.5 nm in order to form an offset spacer 20 on the side surface of the gate electrode, and then the TEOS film is removed by the RIE method, thereby the offset spacer 20 made of the TEOS film is left on the side surface of the gate electrode 13a. In the processes hereto, the active region where the source/drain region is formed is in a bare silicon (bare-Si) state.

Next, the process proceeds to a step of forming the source/drain region. First, the PMOS element region is masked with a resist, and arsenic (As) ions or phosphor (P) ions are injected to the nMOS element region with, for example, an acceleration voltage 0.5 to 2 keV, and a dose amount 8e14 to 2e15, and as shown in FIG. 2G, a shallow extension region 21 of a low impurity concentration is formed. Thereafter, a rapid thermal anneal (RTA) process is performed, and the injected ions are activated.

Next, the nMOS element region is masked with a resist, and BF₂ ions or boron (B) ions are injected to the pMOS element region with, for example, an acceleration voltage 1 to 2 keV, and a dose amount 1e15 to 2e15, whereby a shallow extension region 21 of a low impurity concentration is formed. Thereafter, the RTA process is performed, and the injected ions are activated.

Meanwhile, in order to make the depth of the extension region 21 a predetermined depth or more at the moment of forming the source/drain region, the epitaxial growth may be performed before the stage of the ion injection to the source/drain region, thereby a structure where the substrate surface of the source/drain region is raised, i.e., a raised source/drain region may be realized.

Next, a side wall insulation film of, for example, a three-layer structure to be used for forming a deep source/drain region 27 of a high impurity concentration is formed. First, as shown in FIG. 2H, a TEOS film 23 is deposited on the entire surface, a Si₃N₄ film 24 is deposited, and further a BSG film 25 is deposited thereon. Next, the BSG film 25, the Si₃N₄ film 24, and the TEOS film 23 are etched by the RIE method, thereby a side wall insulation film 26 of a three-layer structure is formed on the side surfaces of the gate electrode 13a, as shown in FIG. 2I. The pMOS element region is masked with a resist, and P ions or As ions are injected to the source/drain region of the nMOS element region with, for example, an acceleration voltage 5 to 20 keV, and a dose amount 2e15 to 5e15. Next, the nMOS element region is masked with a resist, and B ions are injected to the source/drain region of the pMOS element region with, for example, an acceleration voltage 1 to 5 keV, and a dose amount 3e15 to 8e15. Thereafter, a spike RTA process is performed at, for example, 1000° C. to 1100° C., and the injected ions are activated, thereby a deep source/drain region 27 is formed.

(Second Manufacturing Method)

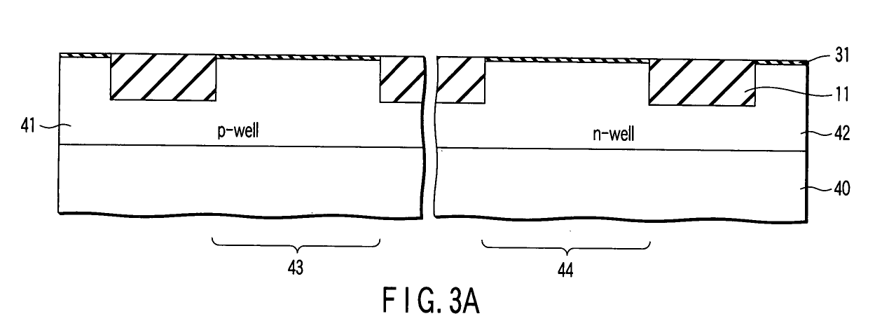

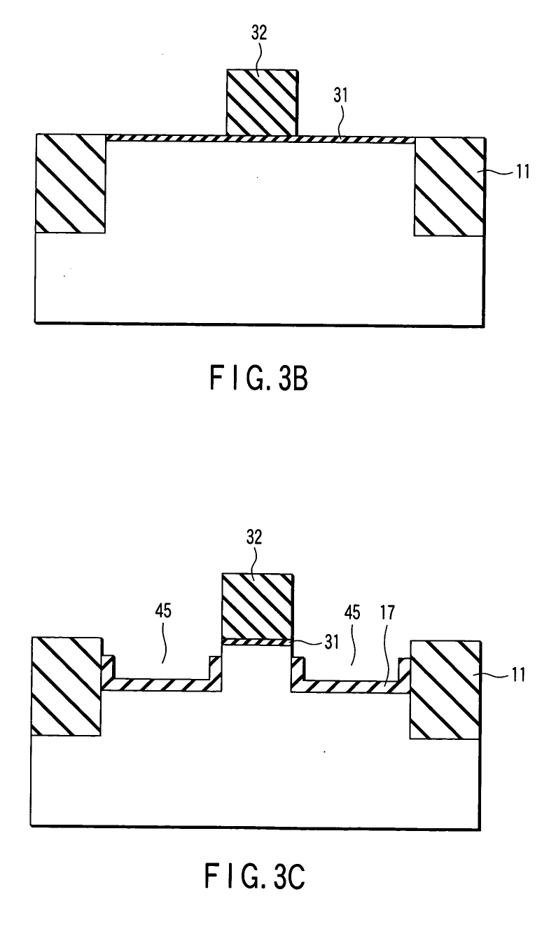

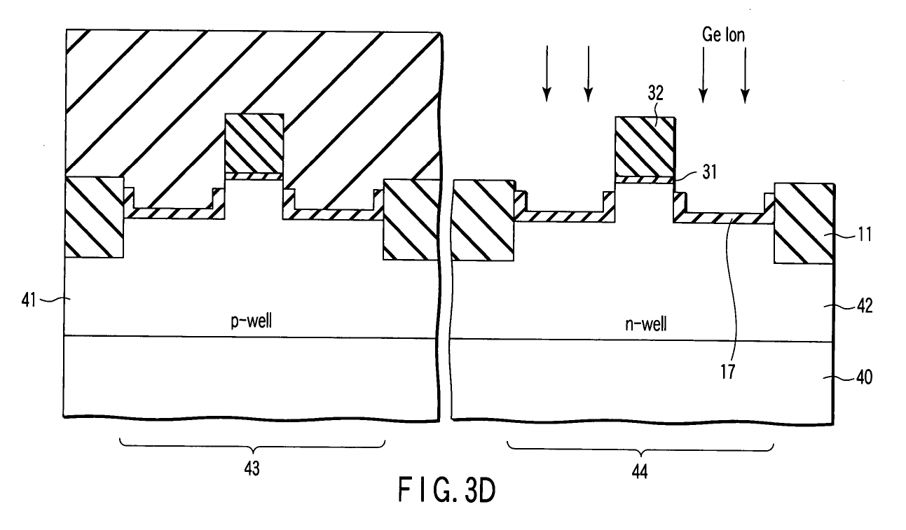

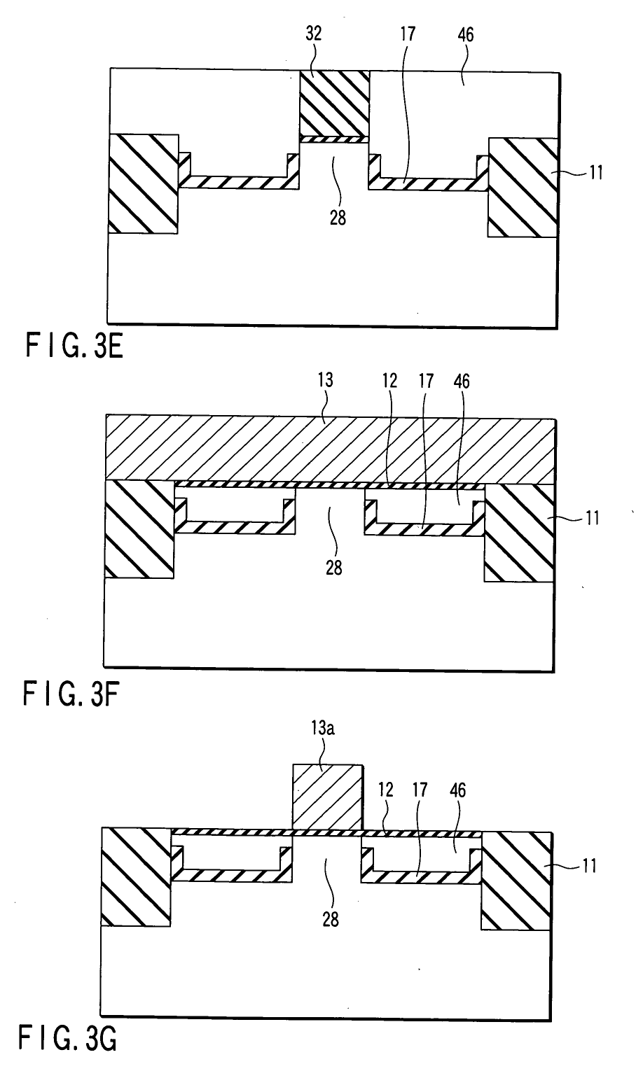

FIGS. 3A to 3G show cross sectional structures in manufacturing the CMOS type semiconductor integrated circuit device in FIG. 1 in accordance with the flow of the gate post-creation process. FIGS. 3A and 3D show the cross sections of the nMOS element region 43 and the pMOS element region 44, and FIGS. 3B, 3C, and 3E to 3G each show an enlarged view of one of the nMOS element region and the pMOS element region, for simplified illustration.

In this manufacturing method, the steps shown in FIGS. 2A to 2E are different from those in the previously explained manufacturing method, and the steps shown in FIGS. 2F to 2I are same as those in the previously explained manufacturing method. Therefore, the same functional components are denoted by the same reference numerals.

First, as shown in FIG. 3A, a shallow trench is formed in the surface region of a Si semiconductor substrate 40 in a state in which a natural oxide film 31 is on the upper surface of the Si semiconductor substrate 40, and an insulation film, for example, a silicon oxide film is filled in the inside thereof and thereby an STI 11 is formed. Then, a p-well 41 and an n-well 42 are formed on the surface region of the Si semiconductor substrate 40.

Next, as shown in FIG. 3B, a Si₃N₄ film 32 is deposited on the entire surface, and a resist mask is formed so as to correspond to the dimension of a channel region 28 under the gate electrode, for example a length of 150 nm, and the Si₃N₄ film 32 is selectively etched by the RIE method. Thereafter, the resist mask is removed.

Next, as shown in FIG. 3C, the portion corresponding to the source/drain region of the Si semiconductor substrate 40 is etched and removed by the RIE method, and thereby a pair of trenches 45 are formed in each element region. At this moment, the etching amount of the Si semiconductor substrate 40, i.e., the depth of the pair of trenches 45 is determined according to the junction depth of the source/drain region of the MOSFET, and the film thickness of an embedded insulation film 17 to be formed later, and is, for example, around 150 nm. Thereafter, the Si₃N₄ film is deposited around 50 nm by, for example, a high temperature thermal CVD method, and thereby the embedded insulation film 17 is formed. The embedded insulation film 17 is formed onto not only the bottom surface of the trench 45 where the Si semiconductor substrate 40 is etched, but also the side surfaces of the trench 45. Namely, the embedded insulation film 17 is composed of a first portion positioned on the bottom surface of each trench 45, and a second portion positioned at the side surfaces of each trench 45 and integrated with the first portion. The upper surface of the second portion is lower than the upper surface of the original substrate 40.

Next, as shown in FIG. 3D, the nMOS element region 43 is masked with a resist, and Ge ions are injected to the embedded insulation film 17 of the pMOS element region 44 with, for example, an acceleration voltage 1 to 5 keV, and a dose amount 3e15 to 8e15. Thereafter, the RTA process is performed, and the injected ions are activated. Thereby, it is possible to ease the tensile stress that works on the channel region in the PMOS element region 44.

Then, as shown in FIG. 3E, epitaxial growth of Si is performed. At this moment, a single crystal Si layer 46 grows with the single crystal Si of the channel region 28, and the inside of each trench 45 and the upper surface thereof are embedded with the single crystal Si layer 46. Subsequently, the Si layer 46 is scraped to the height of the Si₃N₄ film 32 by the CMP.

Next, as shown in FIG. 3F, the upper surface of the single crystal Si layer 46 is etched by the RIE until it gets at the height of the original Si semiconductor substrate 40. Thereafter, the Si₃N₄ film 32 is etched and removed with hot phosphoric acid. After an oxide film is grown, for example, around 1 nm on the Si semiconductor substrate 40, plasma nitriding is performed, and thereby an oxide film 12 whose effective oxide thickness is, for example, 1.3 nm, is formed. Thereafter, a polysilicon film 13 of, for example, 150 nm is deposited thereon.

In a state before gate processing, pre-doping of P ion is performed to the polysilicon film 13 of the nMOS element region with, for example, an acceleration voltage 5 keV, and a dose amount 3e15 to 5e15. Pre-doping is not performed to the polysilicon film 13 of the PMOS element region.

Thereafter, in the same manners as in the process mentioned previously with reference to FIG. 2B, the Si₃N₄ film is deposited on the polysilicon film 13 as a hard mask, for example, around 50 nm, a COM process is performed as a preprocessing, and further a RTO process is performed. Thereafter, an amorphous silicon film is deposited, and an ARC film is deposited thereon. The ARC film and the amorphous silicon film are etched by the RIE method. By isogonic etching, the amorphous silicon film is slimed.

Next, the Si₃N₄ film and the polysilicon film 13 are etched by the RIE method, so that the gate electrode 13a is formed. Thereafter, two layers of amorphous silicon films including the ARC film and the amorphous silicon film 15 on the gate electrode 13a are etched, and further, the Si₃N₄ film is removed with hot phosphoric acid. Next, as a post oxide process of the surface of the gate electrode 13a, an oxide film of 2 nm is formed by the RTO.

Thereafter, in the same manners as in the steps on and after FIG. 2F, a MOSFET having an LDD structure is completed.

In the CMOS type semiconductor integrated circuit devices manufactured by the above two manufacturing methods, the lower region of the channel region 28, that is the bottom surface of the source/drain region of each MOSFET and the side surfaces of the source/drain region, contacts the embedded insulation film 17. Consequently, it is possible to reduce the junction capacitance and the leak current of the source/drain region. Especially, in the case of the MOSFET of the LDD structure, it is possible to restrict the leak current from the deep source/drain region to the lower region of the channel region 28 by the embedded insulation film 17 existing at the side surfaces of the source/drain region and the lower region of the channel region 28. Further, the channel region 28 is interconnected to the Si semiconductor substrate 40. Namely, the Si semiconductor substrate 40 is not insulated, so that it is possible to avoid the self heating effect and the substrate floating effect. Furthermore, the low cost Si semiconductor substrate 40 is used as a bulk substrate, without using the generally highly cost SOI substrate, and therefore, it is possible to manufacture the integrated circuit device at low costs.

Moreover, in the nMOS element region on the Si semiconductor substrate 40, stress that causes tensile stress to work onto the channel region 28 of the nMOSFET by the embedded insulation film 17 formed at the bottom surface of the source/drain region and the side surfaces of the source/drain region and under the lower region of the channel region 28. Therefore, it is possible to control the carrier mobility. In this case, the above stress can be controlled by adjusting the film thickness of the embedded insulation film 17. Namely, the thicker the film thickness is made, the stronger the stress can be made. Further, by adjusting the distance in which the upper surface of the embedded insulation film 17 retreats from the surface of the Si semiconductor substrate, it is possible to adjust the stress that works on the channel region 28 of the nMOS element region and the channel region 28 of the pMOS element region.

The first embodiment mentioned above has explained the case where the embedded insulation film 17 formed by the thermal CVD is used. Namely, the embedded insulation film 17 formed by the thermal CVD has tensile stress as described above. In the pMOSFET where the carrier mobility decreases because the tensile stress works on the channel region 28, predetermined ion seeds, for example, Ge ions are injected into the embedded insulation film 17, and thereby the tensile stress is eased.

On the other hand, it is known that the Si₃N₄ film formed by the plasma CVD has compression stress. Therefore, in the case where an embedded insulation film made of Si₃N₄ is formed by the plasma CVD in the place of the thermal CVD, the PMOSFET region is masked, and predetermined ion seeds, for example, Ge ions are injected into the embedded insulation film of the nMOSFET. Thereby, the compression stress can be eased, and the decrease of the carrier mobility of the nMOSFET can be restricted.

Namely, an embedded insulation film made of Si₃N₄ is formed on the bottom surface and the side surfaces of the source/drain region of the nMOSFET by the plasma CVD, and an embedded insulation film made of Si₃N₄ is formed on the bottom surface and the side surfaces of the source/drain region of the pMOSFET by the plasma CVD. Consequently, it is possible to cause tensile stress to work on the channel region 28 of the nMOSFET, and compression stress on the channel region 28 of the pMOSFET.

Further, when tensile stress is made to work on the channel region of the PMOSFET as mentioned above, the carrier mobility decreases, causing adverse effects on device characteristics, such as a decline in ON-current in some cases. Therefore, in the pMOS element region, it is desirable to use as the embedded insulation film formed on the bottom surface and the side surfaces of the source/drain region, (1) a film having a film quality enough to allow the stress to make compression stress on the channel region of the pMOSFET, or, (2) a film whose linear expansion coefficient is lower than that of Si, and whose tensile stress to work on the channel region of the pMOSFET is weakened. As one example thereof, there is the technology for injecting Ge ions into the embedded insulation film 17 of the pMOSFET region 44, as mentioned above with reference to FIG. 3D.

Meanwhile, in a structure using a distortion Si technology known as one example of means for improving the carrier mobility, a SiGe layer and a Si layer are sequentially formed on a Si semiconductor substrate having a large grating constant, tensile distortion is added to a Si layer to thereby modulate a Si band structure, so that the improvement of carrier mobility is realized. However, in the same manner as the SOI structure mentioned previously, the structure using the distortion Si technology also leads to the self heating effect owing to a SiGe layer of a low heat conductivity rate, high costs owing to the thick film thickness growth of a thick inclined type SiGe buffer layer, and problems on crystal quality such as increased penetration transition owing to a high Ge concentration and the like.

### SECOND EMBODIMENT

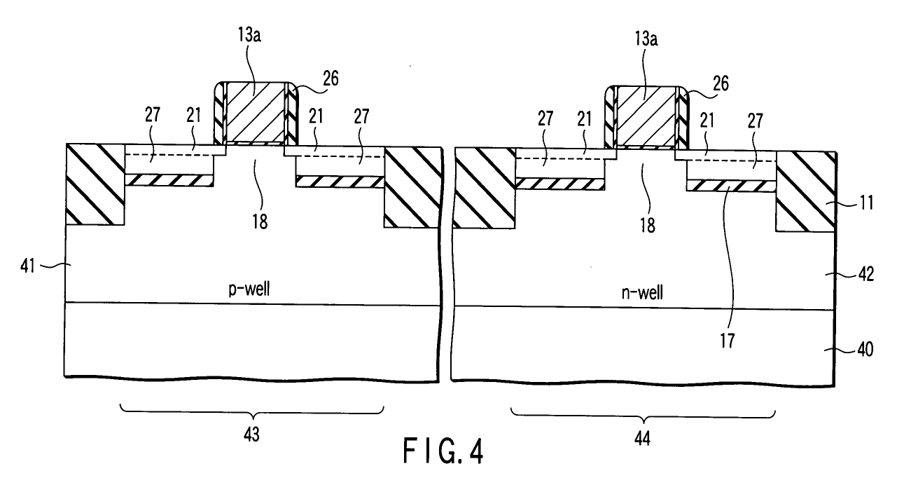

FIG. 4 is a cross sectional view showing an element structure of a CMOS type semiconductor integrated circuit device according to a second embodiment of the invention. In the CMOS type semiconductor integrated circuit device according to the present embodiment, an embedded insulation film 17 is composed of only a first portion positioned on each bottom surface of a pair of trenches, and a second portion positioned on the side surfaces at the lower region of the channel region 28 of a MOSFET is not formed. Namely, as shown in FIG. 4, a modification is made so that the embedded insulation film 17 is formed only on the bottom surface of the source/drain region 27 of the MOSFET. In this case as well, it is possible to reduce the junction capacitance and the leak current of the source/drain region.

Also in the structure of the second embodiment mentioned above, the embedded insulation film is formed on the bottom surface of the source/drain region of the MOSFET, and the channel region of the MOSFET is interconnected to the semiconductor substrate. In this manner, the channel region is not insulated from the semiconductor substrate, and it is possible to avoid the self heating effect and the substrate floating effect. Furthermore, the bottom surface of the source/drain region contacts the embedded insulation film. Therefore, it is possible to reduce the junction capacitance and the leak current of the source/drain region. Moreover, the low cost Si substrate is used as a bulk substrate, and so, it is possible to manufacture the integrated circuit device at low costs.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A MOS type semiconductor integrated circuit device comprising:
an element isolation region which is formed in the surface region of a semiconductor substrate, and isolates the substrate into a plurality of element regions;
a pair of trenches which is formed apart in each of said plurality of element regions, and each has a bottom surface and side surfaces;
an insulation film having at least a first portion positioned on said each bottom surface in the pair of trenches;
a source region and a drain region formed on the insulation film, and formed on the inside of the pair of trenches;
a channel region which is formed between the source region and the drain region, and is interconnected to the semiconductor substrate; and
a gate electrode formed on said each channel region.

2. The MOS type semiconductor integrated circuit device according to claim 1, wherein the source region and the drain region each include an extension region formed in a surface region of the source region and the drain region.

3. The MOS type semiconductor integrated circuit device according to claim 2, wherein the insulation film further has a second portion which is positioned above said each side surface in the pair of trenches, and whose upper surface is lower than the bottom surface of the extension region.

4. The MOS type semiconductor integrated circuit device according to claim 1, wherein said plurality of element regions include a first element region on which an nMOSFET is formed, and a second element region on which a pMOSFET is formed.

5. The MOS type semiconductor integrated circuit device according to claim 4, wherein the insulation film is composed of a material which causes tensile stress to work on the channel region which is formed in the first element region.

6. The MOS type semiconductor integrated circuit device according to claim 5, wherein the insulation film is a thermal CVD insulation film.

7. The MOS type semiconductor integrated circuit device according to claim 6, wherein the semiconductor substrate is a silicon semiconductor substrate, and the insulation film is a silicon nitride film.

8. The MOS type semiconductor integrated circuit device according to claim 7, wherein the silicon nitride film which is formed in the second element region includes Ge.

9. The MOS type semiconductor integrated circuit device according to claim 4, wherein the insulation film is composed of a material which causes compression stress to work on the channel region which is formed in the second element region.

10. The MOS type semiconductor integrated circuit device according to claim 9, wherein the insulation film is a plasma CVD insulation film.

11. The MOS type semiconductor integrated circuit device according to claim 10, wherein the semiconductor substrate is a silicon semiconductor substrate, and the insulation film is a silicon nitride film.

12. The MOS type semiconductor integrated circuit device according to claim 11, wherein the silicon nitride film which is formed in the first element region includes Ge.

13. A method of manufacturing a MOS type semiconductor integrated circuit device, comprising:
forming an element isolation region in a surface region of a silicon semiconductor substrate, and isolating the substrate into a plurality of element regions;
forming a gate electrode on each of said plurality of element regions;
etching and removing the substrate by using said each gate electrode as a mask, and forming a pair of trenches in the substrate of said plurality of element regions;
forming a silicon nitride film composed of a first portion which is positioned on the bottom surface of each of the pair of trenches, and a second portion which is positioned on the side surfaces of the trench and whose upper surface is lower than the upper surface of the substrate before etching for each trench;
performing an epitaxial growth of silicon with the silicon substrate under the gate electrode as a seed, and forming a single crystal silicon layer on the silicon nitride film;
flattening the upper surface of said each single crystal silicon layer; and
introducing impurities into said each single crystal silicon layer and forming a source region and a drain region.

14. The method of manufacturing a MOS type semiconductor integrated circuit device, according to claim 13, wherein, when the source region and the drain region are formed, an extension region is formed in a surface region of said each single crystal silicon layer.

15. The method of manufacturing a MOS type semiconductor integrated circuit device, according to claim 13, wherein, when the substrate is isolated into a plurality of element regions, a first element region on which an nMOSFET is formed and a second element region on which a pMOSFET is formed are formed.

16. The method of manufacturing a MOS type semiconductor integrated circuit device, according to claim 13, wherein the insulation film is formed by a thermal CVD method.

17. The method of manufacturing a MOS type semiconductor integrated circuit device, according to claim 16, further comprising, after forming the silicon nitride film, introducing Ge ions into the silicon nitride film in some element regions of said plurality of element regions.

18. The method of manufacturing a MOS type semiconductor integrated circuit device, according to claim 13, wherein the silicon nitride film is formed by a plasma CVD method.

19. The method of manufacturing a MOS type semiconductor integrated circuit device, according to claim 18, further comprising, after forming the silicon nitride film, introducing Ge ions into a part of the silicon nitride film in some element regions of said plurality of element regions.
